(19) United States
(12) Patent Application Publication
(10) Pub. No.: US 2006/0179380 A1
(43) Pub. Date: Aug. 10, 2006

(54) On-chip electronic hardware debug support units having execution halting capabilities

(76) Inventor: Ivo Tousek, Stockholm (SE)

Correspondence Address: COOPER & DUNHAM, LLP, 1185 AVENUE OF THE AMERICAS, NEW YORK, NY, 10036, US

(21) Appl. No.: 11/036,446

(22) Filed: Jan. 14, 2005

(51) Int. Cl. G06F 11/00; G01R 31/28

(52) U.S. Cl. 714/736

(57) ABSTRACT

A method for debugging electronic hardware includes providing a memory address, providing an expected value for data at the memory address, detecting an actual value for the data at the memory address when the memory address is accessed, determining whether the expected value for the data at the memory address is equal to the actual value for the data at the memory address, and halting execution of the hardware when it is determined that the expected value for the data at the memory address is not equal to the actual value for the data at the memory address.

### BACKGROUND

1. Technical Field

The present invention relates to on-chip electronic hardware support units and, more specifically, to on-chip electronic hardware debugging support units having execution halting capabilities.

2. Description of the Related Art

Digital Signal Processing (DSP) relates to the examination and manipulation of digital representations of electronic signals. Digital signals that are processed using digital signal processing are often digital representations of real-world audio and/or video.

Digital signal processors are special-purpose microprocessors that have been optimized for the processing of digital signals. Digital signal processors are generally designed to handle digital signals in real-time, for example, by utilizing a real-time operating system (RTOS). A RTOS is an operating system that may appear to handle multiple tasks simultaneously, for example, as the tasks are received. The RTOS generally prioritizes tasks and allows for the interruption of low-priority tasks by high-priority tasks. The RTOS generally manages memory in a way that minimizes the length of time a unit of memory is locked by one particular task and minimizes the size of the unit of memory that is locked; allowing tasks to be performed asynchronously while minimizing the opportunity for multiple tasks to try to access the same block of memory at the same time.

Digital signal processors are commonly used in embedded systems. An embedded system is a specific-purpose computer that is integrated into a larger device. Embedded systems generally utilize a small-footprint RTOS that has been customized for a particular purpose. Digital signal processing is often implemented using embedded systems comprising a digital signal processor and a RTOS.

Digital signal processors are generally sophisticated devices that may include one or more microprocessors, memory banks and other electronic elements. Along with digital signal processors, embedded systems may contain additional elements such as sub-system processors/accelerators, firmware and/or other microprocessors and integrated circuits.

When designing electronic elements such as embedded systems, digital signal processors and/or additional elements, it is common for the electronic elements, at least in the early stages of development, to function in an unplanned and/or unwanted way due to one or more sources of error (bugs) in the element's design. The process of identifying and removing these bugs from the electronic elements is called debugging.

Debugging can be cumbersome and difficult. This difficulty is in-part caused by the extraordinary complexity of modern electronic elements. Often a bug is observable only by one or more generic problems, such as a malfunction or crash. It can therefore be difficult to determine what problem in the electronic element's design gave rise to the bug.

Debugging electronic elements can be especially difficult as it is very hard to see exactly what has happened inside the electronic element being debugged that caused it to crash or otherwise malfunction. Often times, all that can be observed is the presence of a bug and solutions must be obtained through trial-and-error rather than through deductive reasoning.

It is therefore desirable to facilitate debugging of electronic elements, for example digital signal processors and/or integrated circuits.

### SUMMARY

A method for debugging electronic hardware includes providing a memory address, providing an expected value for data at the memory address, detecting an actual value for the data at the memory address when the memory address is accessed, determining whether the expected value for the data at the memory address is equal to the actual value for the data at the memory address, and halting execution of the hardware when it is determined that the expected value for the data at the memory address is not equal to the actual value for the data at the memory address.

A system for debugging electronic hardware includes a memory address, an expected value for data at the memory address, an actual-value detecting unit for detecting an actual value for the data at the memory address when the memory address is accessed, a determining unit for determining whether the expected value for the data at the memory address is equal to the actual value for the data at the memory address, and a halting unit for halting execution of the hardware when it is determined that the expected value for the data at the memory address is not equal to the actual value for the memory address.

A computer system includes a processor and a program storage device readable by the computer system, embodying a program of instructions executable by the processor to perform steps for debugging electronic hardware. The method includes providing a memory address, providing an expected value for data at the memory address, detecting an actual value for the data at the memory address when the memory address is accessed, determining whether the expected value for the data at the memory address is equal to the actual value for the memory address, and halting execution of the hardware when it is determined that the expected value for the data at the memory address is not equal to the actual value for the data at the memory address.

### BRIEF DESCRIPTION OF THE DRAWINGS

A more complete appreciation of the present invention and many of the attendant advantages thereof will be readily obtained as the same becomes better understood by reference to the following detailed description when considered in connection with the accompanying drawings, wherein:

FIG. 1 is a block diagram showing a configuration for debugging a system under test according to an embodiment of the present invention;

FIG. 2 is a flow chart illustrating the observation of a system under test as it executes and the halting of the execution when a bug is detected according to an embodiment of the present invention;

FIG. 3 is a circuit diagram showing an example of a debugging unit according to an embodiment of the present invention;

FIG. 4 is a circuit diagram showing an example of a DBG according to another embodiment of the present invention;

FIG. 5 is a circuit diagram showing an example of a DBG according to another embodiment of the present invention; and

FIG. 6 is a block diagram showing an example of a computer system which may implement the method and system of the present invention.

### DETAILED DESCRIPTION

In describing the preferred embodiments of the present invention illustrated in the drawings, specific terminology is employed for sake of clarity. However, the present invention is not intended to be limited to the specific terminology so selected, and it is to be understood that each specific element includes all technical equivalents which operate in a similar manner.

As mentioned above, one of the extraordinary difficulties of debugging hardware, for example electronic devices such as digital signal processors and related devices, is the lack of ability to observe the inner workings of the electronic devices under test. Additionally, even where visibility is provided for, the extraordinary complexity and high speed of these electronic devices makes it difficult to pinpoint where and when a problem is occurring so the problem can be effectively isolated and remedied.

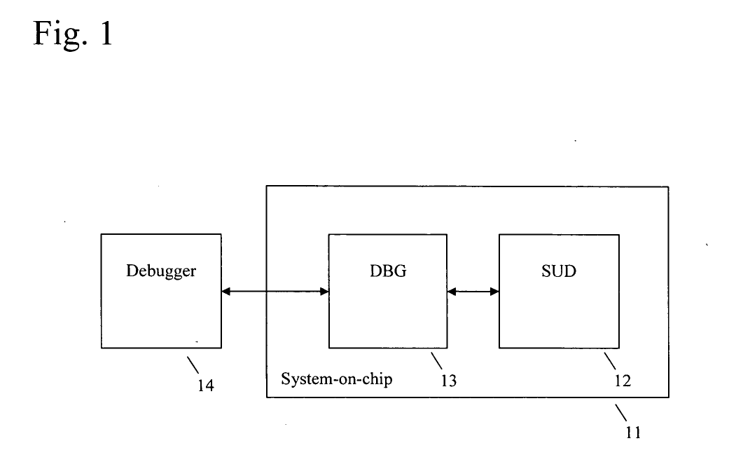

FIG. 1 is a block diagram showing one embodiment of the present invention. According to this embodiment of the present invention, a hardware debug unit (DBG) 13 may be integrated into the circuit element 11 of the electronic device to be tested 12. For example, the DBG 13 may be integrated into a microchip 11 that contains the electronic device to be tested 12. In this context, the electronic device to be tested 12 may be called a system under debug (SUD) 12. Where the DBG 13 is integrated into a microchip, the DBG 13 may be considered an on-chip debug unit. The SUD 12 may then be considered an on-chip system under debug.

The DBG 13 may provide dedicated hardware support to allow an external debugger 14 to communicate with the SUD 12. The DBG 13 may act as an interface between the SUD 12 and the debugger 14. For example, the DBG 13 may be able to interface with the SUD 12 when the SUD 12 is in a debug mode. The DBG 13 may therefore provide a means for the debugger 14 to peer inside the SUD 12 and observe its operation while minimizing the extent to which the processing capacity of the SUD 12 must be utilized to perform testing. This may allow the SUD 12 to function as it would in normal operation, potentially increasing the effectiveness of debugging.

A debugger 14 may download debug information into the DBG 13. For example, the debugger 14 may download debug information into one or more registers within the DBG 13. The DBG 13 may then access information within the SUD 12 when the SUD is in a debugging mode. While in debug mode, the SUD 12 may also relay its status to the DBG 13.

The DBG 13 may be able to observe and/or control the operation of the SUD 12 during normal operation, for example, by observing the operation of the SUD 12 as it functions within a greater system, for example a digital signal processor system. The DBG 13 may additionally be able to observe and/or control the operation of the SUD 12 by its self by simulating the inputs that the SUD 12 would receive if it were functioning as part of a greater system.

For example, the DBG 13 may support the debugger 14 by being able to provide the SUD 12 with values, for example memory addresses and data, that may be used to test how the SUD 12 operates under a particular set of conditions. Additionally, the DBG 13 may support the debugger 14 by being able to examine values as they are read from the SUD 12 and/or examine values as they are written to the SUD 12. In so doing, the DBG 13 may be able to provide the SUD 12 with a set of inputs and obtain from the SUD 12 a set of outputs that may be used to determine if the SUD 12 is functioning as designed and/or to isolate a bug.

The debugger 14 may be a computer system or an embedded system that may be able to execute a debugging application for debugging the SUD 12. The debugger 14 may allow the system designer to use the DBG 13 to control and monitor the performance of the SUD 12, for example through the debugging application.

There are many different forms of debuggers 14 that may be used either individually or in a group of two or more. Different debuggers 14 may support different debugging features. Some examples of debugging features include: system boot, start/stop/resume software execution, setting of program addresses or data breakpoints, reading/writing on-chip memory address locations or registers, software instruction stepping and software execution trace monitoring.

According to one embodiment of the present invention, debugging may be improved by using the DBG to observe the operation of the SUD and stop the execution of the SUD when a bug is detected, even in situations when the bug would not by its self be capable of halting SUD execution or producing an observable error.

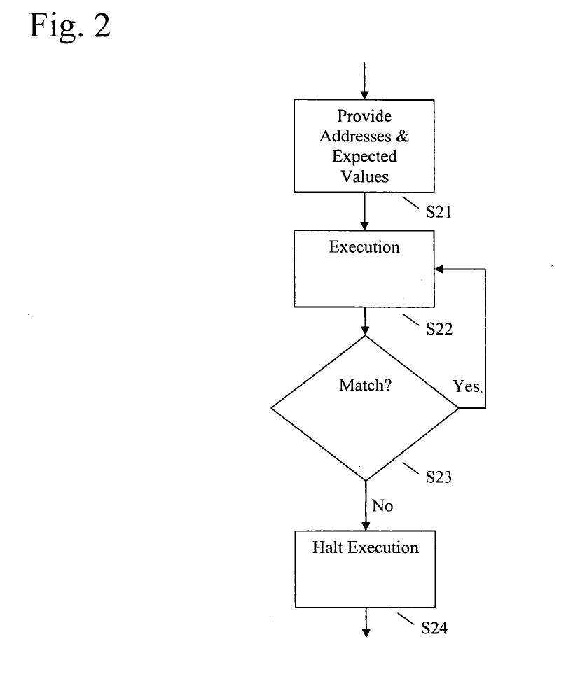

FIG. 2 is a flow chart illustrating the observation of the SUD as it executes and the halting of the execution when a bug is detected according to an embodiment of the present invention. An SUD may contain memory internal to the SUD (on-chip memory). On-chip memory may be, for example, synchronous random access memory (SRAM). The signs of proper execution of the SUD may be known by examining the on-chip memory and comparing the content of the memory to expected values. For example, the design specifications of the SUD may be used to ascertain expected values for data at particular memory locations within the SUD, for example, at a particular time during execution of the SUD and/or when the SUD is provided with a particular set of inputs. The expected memory values may represent expected values for values that are read from the SUD and/or expected values for values that are written to the SUD. These addresses and expected values may be provided to the debugger (Step S21). The SUD may then be executed (Step S22). Executing the SUD may comprise executing an application within the SUD. For example, where the SUD is a digital signal processor, executing the SUD may comprise executing an application within the digital signal processor. As the SUD executes, actual values may be observed from the SUD. These actual values may be examined to determine whether the actual values match the provided expected values (Step S23). For example, a set of preconditions may be provided with each memory address and expected value, and a particular memory read and/or memory write may be checked against its corresponding expected value when the corresponding precondition occurs. For example, where the precondition is a fixed time, when that time occurs, the actual value for the corresponding memory access (read and/or write) may be checked against the corresponding expected value. When the actual value matches the provided expected value (Yes, Step S23) then the SUD may continue to execute S22 until its natural termination. When the actual value does not match the provided expected value (No, Step S23) then execution of the SUD may be halted (Step S24).

By halting the execution of the SUD upon a mismatch, bugs may be isolated and identified thereby aiding in the debugging of the SUD. After the SUD has been halted, one or more additional debugger functions may be performed. For example, memory addresses may be examined, execution may be resumed, program addresses may be set, new breakpoints introduced, stepping through execution steps, and/or any other debugging feature, for example, the debugging features listed above.

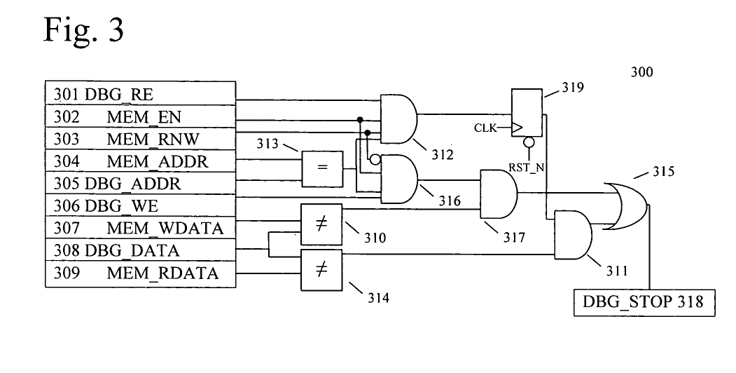

While embodiments of this invention may be implemented in many possible ways, FIG. 3 is a circuit diagram showing an example of a DBG 300 according to an embodiment of the present invention. As described above, a debugger (not shown) may send a memory address and a corresponding expected value to the DBG 300. The DBG 300 may have a “DBG_ADDR” register 305 to receive the memory address and a “DBG_DATA” register 308 to receive the corresponding expected value.

On some occasions it may be preferred to check to see if a value is as expected when the value is read, on other occasions it may be preferred to check to see if a value is as expected when the value is written. The debugger may specify to the DBG whether to trigger a check on a read, to trigger a check on a write or on both a read and a write. To specify a trigger on a read, the debugger may send a logical 1 to a “DBG_RE” register 301. To specify a trigger on write, the debugger may send a logical 1 to a “DBG_WE” register 306. When both the DBG_RE register 301 and the DBG_WE 306 registers are sent a logical 1, the debugger may trigger on either a read or a write. When both the DBG_RE register 301 and the DBG_WE 306 registers are sent a logical 0, the triggering logic may be disabled.

As the SUD executes, various readings from the SUD may be sent to the DBG 300. For example, when the SUD is actively accessing memory, a “MEM_EN” signal 302 may receive a logical 1. When the SUD is reading memory, a “MEM_RNW” signal 303 may receive a logical 1 and the “MEM_EN” signal may receive a logical 1. When the SUD is writing memory, the “MEM_RNW” signal 303 may receive a logical 0 and the “MEM_EN” signal may receive a logical 1. A “MEM_ADDR” signal 304 may then receive the address of the active memory location. A “MEM_RDATA” signal 309 may detect the data that is read from that memory location and a “MEM_WDATA” signal 307 may detect the data that is written to that memory location.

In this example, memory read data and memory write data need not be received on a common bus. Such behavior being consistent with synchronous SRAM.

The circuit logic illustrated in FIG. 3 may then trigger a halt of SUD execution (an execution stop) by sending a logical 1 to a “DBG_STOP” register 318 when there is a mismatch between an expected memory value and an actual memory value. The circuit logic is explained in detail below.

An “OR gate” 315 may send a logical 1 to the DBG_STOP register 318 when either “AND gate” 311 or “AND gate” 317 show a logical 1. “AND gate” 317 may register a logical 1 when “AND gate” 316 and “not equal comparator” 310 both show a logical 1. The “not equal comparator” 310 may show a logical 1 when the data in the DBG_DATA register 308 (the expected value) does not match the data in the MEM_WDATA signal 307 (the actual value). The “AND gate” 316 may show a logical 1 when the MEM_EN signal 302 shows a logical 1 (the SUD is actively accessing memory), the MEM_RNW signal 303 shows a logical 0 (the SUD is writing memory), the DBG_WE register 306 shows a logical 1 (memory write is the trigger), and a comparator 313 all show a logical 1. The comparator 313 may show a logical 1 when the MEM_ADDR signal 304 (the memory address currently in use by the SUD) is equal to the DBG_ADDR register 305 (the memory address to be checked for the expected value).

The “AND gate” 311 may show a logical 1 when the “not equal comparator” 314 shows a logical 1 and the flip-flop 319 presents a logical 1 at its output. The not equal comparator 314 may show a logical 1 when the DBG_DATA 308 does not match the MEM_RDATA 309. The flip-flop 319 may show a logical 1 when the “AND gate” 312 shows a logical 1. The flip-flop 319 may delay the signal shown from the “AND gate” 312 by one clock cycle to coincide with the comparison between expected and actual data. The “AND gate” 312 may show a logical 1 when the comparator 313 shows a logical 1 (as described above), the MEM_EN signal 302 shows a logical 1 (the SUD is actively accessing memory), the MEM_RNW signal 303 shows a logical 1 (the SUD is reading memory), and the DBG_RE register 301 all show a logical 1 (memory read is a trigger).

Where the SUD is capable of accessing multiple memory locations simultaneously, the DBG may utilize multiple instances of the above-described logic to monitor each instance of accessing memory simultaneously.

Moreover, the debugger may be programmed to automatically reconfigure the logic between consecutive memory accesses. For example, the debugger may store multiple memory addresses and corresponding expected values and the debugger can change the active address and/or expected value as desired. This may be accomplished, for example, by setting a breakpoint after each memory access to give the debugger time to change the active address and/or expected value.

For example, the debugger could store an array of memory addresses and corresponding expected data values, for example 1024 memory addresses and corresponding expected data values. When the SUD enters debug mode or when a breakpoint is triggered, the debugger may check for a data mismatch. When the check was initiated by a triggered breakpoint, the debugger may then configure the DBG for the next address/expected data value pair and restart the SUD.

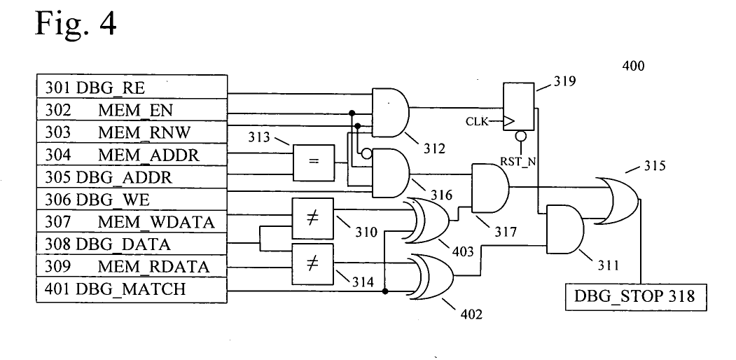

FIG. 4 is a circuit diagram showing an example of a DBG 400 according to another embodiment of the present invention. According to this embodiment, two “XOR gates” 402 and 403 may be inserted into the logic shown in FIG. 3. The first “XOR gate” 402 may take as input the output of the not-equal comparator 314 and a DBG_MATCH control bit 401. Therefore, when DBG_MATCH 401 receives a logical 1 from the debugger, then the output from the not-equal comparator 314 will be effectively inverted. When the DBG_MATCH 401 receives a logical 0, then the logic will function as it does in the embodiment shown in FIG. 3. Similarly, the second “XOR gate” 403 may take as input the output of the not-equal comparator 310 and the DBG_MATCH control bit 401. Therefore, when the DBG_MATCH 401 receives a logical 1 from the debugger, then the output from the not-equal comparator 310 will be effectively inverted. This embodiment therefore allows the DBG 400 to be programmed to send a logical 1 to the DBG_STOP signal 318, thereby stopping execution of the SUD, upon a match as opposed to a mismatch.

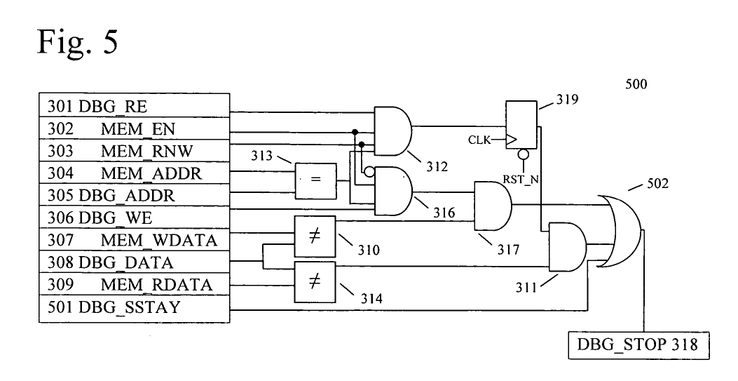

FIG. 5 is a circuit diagram showing an example of a DBG 500 according to another embodiment of the present invention. A DBG_SSTAY register 501 may be connected to a three-input “OR gate” 502 that may replace the “OR gate” 315 of FIGS. 3 and 4. The debugger may send DBG_SSTAY 501 a logical 1 to stop SUD execution and maintain a stopped state. The debugger may alternatively send DBG_SSTAY 501 a logical 0 to allow for normal operation as described above.

It should be noted that the circuit diagrams shown in FIGS. 3, 4 and 5 are intended to be illustrative of certain features described in the specification and are not intended to represent complete embodiments of the present disclosure.

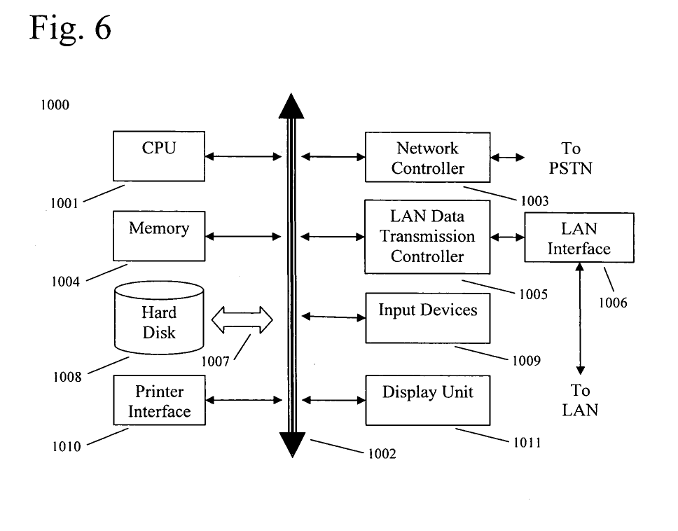

FIG. 6 is a block diagram showing an example of a computer system which may implement the method and system of the present invention. The system and method of the present invention may be implemented in the form of a software application running on a computer system, for example, a mainframe, personal computer (PC), handheld computer, server, etc. The software application may be stored on a recording media locally accessible by the computer system and accessible via a hard wired or wireless connection to a network, for example, a local area network, or the Internet.

The computer system referred to generally as system 1000 may include, for example, a central processing unit (CPU) 1001, random access memory (RAM) 1004, a printer interface 1010, a display unit 1011, a local area network (LAN) data transmission controller 1005, a LAN interface 1006, a network controller 1003, an internal bus 1002, and one or more input devices 1009, for example, a keyboard, mouse etc. As shown, the system 1000 may be connected to a data storage device, for example, a hard disk, 1008 via a link 1007.

The above specific embodiments are illustrative,.and many variations can be introduced on these embodiments without departing from the spirit of the invention or from the scope of the appended claims. For example, elements and/or features of different illustrative embodiments may be combined with each other and/or substituted for each other within the scope of this invention and appended claims.

What is claimed is:

1. A method for debugging electronic hardware, comprising:
providing a memory address;
providing an expected value for data at the memory address;
detecting an actual value for the data at the memory address when the memory address is accessed;
determining whether the expected value for the data at the memory address is equal to the actual value for the data at the memory address; and
halting execution of the hardware when it is determined that the expected value for the data at the memory address is not equal to the actual value for the data at the memory address.

2. The method of claim 1, wherein the accessing of the memory address comprises reading from the memory address or writing to the memory address.

3. The method of claim 1, wherein:
multiple memory addresses are provided;
multiple expected values are provided with one expected value corresponding to each of the multiple memory addresses;
multiple actual values are read with one actual value corresponding to each of the multiple memory addresses;
for each of the multiple memory address, it is determined whether the one corresponding expected value is equal to the one corresponding actual value; and
the execution of the hardware is halted when it is determined that any one of the multiple expected vales is not equal to its corresponding actual value for a given memory address.

4. The method of claim 3, wherein the multiple memory addresses and the multiple expected values are provided within an array of memory addresses and expected values.

5. The method of claim 1, wherein the step of halting of the execution of the hardware comprises halting the execution of an application running on the hardware.

6. The method of claim 1, wherein the step of detecting an actual value for the data at the memory address when the memory address is accessed occurs at a predetermined point.

7. The method of claim 1, wherein the step of detecting an actual value for the data at the memory address when the memory address is accessed is triggered when the hardware has executed a read command on the memory address.

8. The method of claim 1, wherein the step of detecting an actual value for the data at the memory address when the memory address is accessed is triggered when the hardware has executed a write command on the memory address.

9. A system for debugging electronic hardware, comprising:
a memory address;
an expected value for data at the memory address;
an actual-value detecting unit for detecting an actual value for the data at the memory address when the memory address is accessed;
a determining unit for determining whether the expected value for the data at the memory address is equal to the actual value for the data at the memory address; and
a halting unit for halting execution of the hardware when it is determined that the expected value for the data at the memory address is not equal to the actual value for the data at the memory address.

10. The system of claim 9, wherein:
multiple memory addresses are provided;
multiple expected values are provided with one expected value corresponding to each of the multiple memory addresses;
multiple actual values are detected with one actual value corresponding to each of the multiple memory addresses;
for each of the multiple memory address, the determining unit determines whether the one corresponding expected value is equal to the one corresponding actual value; and
the halting unit halts execution of the hardware when it is determined that any one of the multiple expected vales is not equal to its corresponding actual value for a given memory address.

11. The system of claim 10, wherein the multiple memory addresses and the data at the multiple expected values are provided within an array of memory addresses and expected values.

12. The system of claim 9, wherein the hardware comprises a system under debug.

13. The system of claim 9, wherein the hardware comprises a digital signal processor.

14. The system of claim 9, wherein the hardware comprises a microchip.

15. The system of claim 9, wherein the memory address is internal to the hardware.

16. The system of claim 9, wherein the detecting unit, the determining unit and the halting unit comprise a hardware debugging unit.

17. The system of claim 16, wherein the hardware debugging unit is located on the same electronic element as the hardware.

18. The system of claim 17, wherein the electronic element is a microchip.

19. The system of claim 16, wherein the hardware debugging unit interfaces with a debugger.

20. The system of claim 19, wherein the debugger is a computer system running one or more debugging applications for debugging the hardware.

21. A computer system comprising:
a processor; and
a program storage device readable by the computer system, embodying a program of instructions executable by the processor to perform steps for debugging electronic hardware, the steps comprising:
providing a memory address;
providing an expected value for data at the memory address;
detecting an actual value for the data at the memory address when the memory address is accessed;
determining whether the expected value for the data at the memory address is equal to the actual value for the data at the memory address; and
halting execution of the hardware when it is determined that the expected value for the data at the memory address is not equal to the actual value for the data at the memory address.

22. The computer system of claim 21, wherein the accessing of the memory address comprises reading from the memory address.

23. The computer system of claim 21, wherein the accessing of the memory address comprises writing to the memory address.

24. The computer system of claim 21, wherein the accessing of the memory address comprises reading from the memory address or writing to the memory address.

25. The computer system of claim 21, wherein:
multiple memory addresses are provided;
multiple expected values are provided with one expected value corresponding to each of the multiple memory addresses;
multiple actual values are read with one actual value corresponding to each of the multiple memory addresses;
for each of the multiple memory address, it is determined whether the one corresponding expected value is equal to the one corresponding actual value; and
the execution of the hardware is halted when it is determined that any one of the multiple expected vales is not equal to its corresponding actual value for a given memory address.

26. The computer system of claim 21, wherein the step of detecting an actual value for the data at the memory address when the memory address is accessed is triggered when the hardware has executed a read command on the memory address.

27. The computer system of claim 21, wherein the step of detecting an actual value for the data at the memory address when the memory address is accessed is triggered when the hardware has executed a write command on the memory address.
